(19) United States
(12) Patent Application Publication
(10) Pub. No.: US 2026/0197007 A1
(43) Pub. Date: Jul. 9, 2026

(54) Phase-Locked Loop with Synchronized Clock Signals

(71) Applicant: Robert Bosch GmbH, Stuttgart (DE)

(72) Inventors: Michael WICKERT, Dresden (DE); Pablo CRUZ DATO, Valencia (ES); Reiner SCHNITZER, Reutlingen (DE)

(21) Appl. No.: 19/411,720

(22) Filed: Dec. 8, 2025

(30) Foreign Application Priority Data
Dec. 17, 2024 (DE) 10 2024 212 025.1

(51) Int. Cl. H03L 7/093

(52) U.S. Cl. CPC H03L 7/093; H03L 2207/10

(57) ABSTRACT

A phase-locked loop. The phase-locked loop has a phase ascertaining unit for detecting a phase of a reference signal and outputting a measurement signal, a phase deviation ascertaining unit generating an error signal from the measurement signal and a target signal, a loop filter for filtering the error signal, a modulator unit for modulating the filtered error signal and generating a tune signal, and an oscillator for generating an output signal from the tune signal. A feedback signal formed from an output signal of the phase-locked loop is supplied to the phase ascertaining unit. The phase-locked loop includes: a divider unit configured to generate a modulator clock pulse signal from an oscillator clock pulse signal of the oscillator and to supply the modulator clock pulse signal to the modulator unit, and a sampler unit configured to detect a mismatch between the reference signal and the modulator clock pulse signal.

### FIELD

The present disclosure relates to a phase-locked loop. The phase-locked loop has a modulator. In so doing, a clock pulse signal of the modulation is adapted to an external reference.

### BACKGROUND INFORMATION

In digital phase-locked loops, it is conventional, for example, to use delta-sigma modulation. The start of modulation in a digital phase-locked loop is inherently tied to available clock pulse edges of the modulator clock pulse since these control the changes in the tune signal generated by the modulator. If this clock pulse signal is derived from the oscillator clock pulse, the phase relationship of the reference signal to the oscillator can in fact be ascertained by phase measurement, but not the phase relationship of the reference clock pulse to the modulator clock pulse.

### SUMMARY

A phase-locked loop according to the present disclosure with a modulator clock pulse derived from the oscillator enables reset-free clock pulse dividers which are characterized by low leakage currents and high-speed operation. To this end, it is provided that the internal divider state is sampled and/or the phase counter is used for (some of) the divider stages, wherein the divider is provided to generate the modulator clock pulse from the oscillator clock pulse.

The phase-locked loop has a phase ascertaining unit, a phase deviation ascertaining unit, a loop filter, a modulator unit and an oscillator, which is in particular a voltage-controlled oscillator. The phase ascertaining unit is used to detect a phase difference between a reference signal and a feedback signal and to output a measurement signal φₘₑₐₛ representing the phase difference. The phase deviation ascertaining unit is used to generate an error signal φₑᵣᵣ from the measurement signal φₘₑₐₛ and from a target signal φ_{tgt}. The loop filter is provided to filter the error signal φₑᵣᵣ. The modulator unit is used to modulate the filtered error signal and to generate a tune signal, wherein the oscillator is configured to generate an output signal from the tune signal.

The phase ascertaining unit receives a feedback signal derived from an output signal of the phase-locked loop. Thus, a control loop is formed that regulates a phase of the output signal.

Furthermore, the phase-locked loop has a divider unit, for example a frequency divider unit. The divider unit is configured to create a modulator clock pulse signal from an oscillator clock pulse signal of the oscillator. The phase-locked loop is configured to supply the modulator clock pulse signal to the modulator unit. This means that the start of the modulation depends on the presence of the oscillator clock pulse signal. Due to the creation of the modulator clock pulse signal from the oscillator clock pulse signal, a defined phase relationship between the modulator clock pulse signal and the oscillator clock pulse signal is naturally known. The present disclosure also makes it possible to ascertain the phase relationship between the modulator clock pulse signal and the oscillator clock pulse signal in order to achieve precise synchronization of the modulation.

The phase-locked loop accordingly has a sampler unit that is configured to detect a mismatch between the reference signal and the modulator clock pulse signal. The phase deviation ascertaining unit is configured to account for this mismatch when ascertaining the fault signal φₑᵣᵣ. This makes it possible to align the modulation with the reference signal.

Preferred developments and example embodiments are disclosed herein.

The sampler unit is preferably configured to sample a state of flip-flops of the divider unit. In this way, the state of the divider unit can be detected. From the state of the divider unit, the modulator clock pulse signal that was generated by the divider unit can be directly inferred. It is provided that the sampler unit is configured to perform each sampling step according to the clock pulse of the reference signal. In this way, the mismatch between the reference signal and the modulator clock pulse signal can be ascertained.

The divider unit advantageously has an N-bit counter module for detecting the clock pulses of the oscillator clock pulse signal. In this case, N is a natural number and accordingly indicates the size of the counter module. One of the N-bits can be output as a modulator clock pulse signal, which results in a division. By selecting the appropriate bit, a desired division ratio can be set as a power of 2. In this case, the sampler unit has at least one sampler for sampling the N-bits of the counter module. The sampler can be controlled by a data output of a control flip-flop. Particularly advantageously, there are a plurality of samplers, in particular two, wherein each sampler has its own control flip-flop. One of the two samplers is provided for rising edges, the other sampler for falling edges. Accordingly, the oscillator clock pulse signal can be considered both positively as well as negatively. This enables reliable detection of the oscillator clock pulse signal. A data input of the control flip-flop is the reference signal. A clock pulse input of the control flip-flop is the oscillator clock pulse signal. If a plurality of samplers and therefore a plurality of control flip-flops are present, it is provided that one of the control flip-flops as a clock pulse input uses the oscillator clock pulse signal inverted in order to thereby react to falling edges. The sampler unit also has a computing unit that is configured to ascertain the mismatch on the basis of the division ratio of the divider unit and the output of the sampler. Since the division ratio is a power of 2, this can be done very easily. In particular, the current duration t_{lag} until the next rising edge of the modulator clock pulse signal can be easily ascertained from the following formula:

$${t}_{lag} = {T}_{OSC} \times ( \frac{DIV}{2} - cnt\_samp )$$

In this regard, T_{OSC} is the period of the oscillator, DIV the division ratio and cnt_samp the sampler edition.

Particularly advantageously, according to the present disclosure, the divider unit has additional logic for realizing further division ratios that are not powers of two. One type of implementation is additional shift registers. The additional shift register is formed in particular by interconnected flip-flops. The additional shift register is clocked by one of the N output bits of the counter module. In this way, divider ratios that are not a power of 2 can be realized. For this purpose, a bit of the additional shift register can be output as a modulator clock pulse signal instead of the bit of the counter module clocking the additional shift register. In other words, the clock pulse of this bit is divided again by the additional shift register. The size of the additional shift register serves to adjust this subdivision, which allows any desired division ratios to be achieved in the final result.

In this case, the sampler unit also samples the additional shift register. For this purpose, the sampler unit has at least one additional sampler, controllable by the control flip-flop, for sampling the additional shift register. In this case as well, it is preferably provided to use two additional samplers, wherein one of them can be controlled by the control flip-flop for rising edges and the other by the control flip-flop for falling edges. The computing unit is configured to ascertain the deviation on the basis of the division ratio of the divider unit and the output of the sampler as well as of the additional sampler. In particular, the current duration t_{lag} until the next rising edge of the modulator clock pulse signal can be easily ascertained from the following formula:

$${t}_{l a g} = {T}_{O S C} \times ( \frac{DIV}{2} - 2 k \times t h e r m 2 b i n ( d i {v}_{s a m p} ) - cnt\_samp [ k - 1 ] )$$

In this case, T_{OSC} is the period of the oscillator, DIV is the divider ratio, div_samp is the output of the additional sampler, and cnt_samp[k−1] is the output of the sampler concerning the bits clocking the additional sampler k. The function therm2bin(x) is a classic thermometer code for binary code conversion, i.e. for example with 3 bits: 000->0, 001->1, 011->2, 111->3, 110->4, 100->5.

In an alternative embodiment of the present disclosure, the sampler unit preferably has an N-bit counter module for detecting the clock pulses of the oscillator clock pulse signal, wherein N is a natural number. The divider unit is configured to output the modulator clock pulse signal. Furthermore, it is preferably provided that the sampler unit has at least one sampler for sampling the N-bits of the counter module, which sampler can be controlled by a data output of a control flip-flop. Particularly advantageously, there are a plurality of samplers, in particular two, wherein each sampler has its own control flip-flop. One of the two samplers is provided for rising edges, the other sampler for falling edges. Accordingly, the oscillator clock pulse signal can be considered both positively as well as negatively. This enables reliable detection of the oscillator clock pulse signal. A data input of the control flip-flop is the reference signal. A clock pulse input of the control flip-flop is the oscillator clock pulse signal. If a plurality of samplers and therefore a plurality of control flip-flops are present, it is provided that one of the control flip-flops as a clock pulse input uses the oscillator clock pulse signal inverted in order to thereby react to falling edges. In this alternative embodiment, the divider unit and the sampler unit are, in particular, configured to be completely separate. In this case, the sampler unit also samples the divider unit. For this purpose, the sampler unit has at least one additional sampler, controllable by the control flip-flop, for sampling the divider unit. In this case as well, it is preferably provided to use two additional samplers, wherein one of them can be controlled by the control flip-flop for rising edges and the other by the control flip-flop for falling edges. The sampler unit also has a computing unit configured to ascertain the mismatch on the basis of the division ratio of the divider unit and the output of the sampler as well as of the additional sampler. In particular, as in the other embodiments, the current duration t_{lag} can be ascertained until the next rising edge of the modulator clock pulse signal, wherein the formula to be used for this purpose is specific to the exact embodiment of the divider unit, in particular specific to the concrete implementation of the divider unit by an electrical circuit.

According to an example embodiment, the phase-locked loop preferably has a time setting unit. The time setting unit is configured to ascertain an offset φ_{off} from the mismatch between the modulator clock pulse signal and the reference signal. The offset φ_{off} can be supplied to the phase deviation ascertaining unit for generating the error signal φₑᵣᵣ from the measurement signal φₘₑₐₛ, the offset φ_{off} and the target signal φ_{tgt}. This makes it possible to take the mismatch into account during modulation. This ensures that the modulation is correctly aligned with the reference signal.

The modulator unit preferably has a modulator and a scrambler installed downstream of the modulator. The scrambler is used primarily for mismatch shaping and/or transition control. The scrambler is preferably configured to provide metadata that describe basic properties of the selection of active elements of the oscillator. The modulator unit also preferably features an impairment module configured to ascertain signal impairment from the scrambler metadata and from predefined calibration data. Additionally, the impairment module is configured to feed signal impairments back to the modulator. Thus, the modulator can take the impairments of the active elements into account in the next modulation step. This allows the effects of many detailed impairments to be taken into account without the need for highly complex or even impossible oscillator models. The phase-locked loop thus exhibits high modulation accuracy while being cost-effective and simple to implement.

The modulator is specifically a delta-sigma modulator. This allows, in particular, the creation of a digital tune word as a tune signal. A digital phase-locked loop is particularly advantageous for the entire phase-locked loop.

The phase-locked loop preferably has a specification unit. The specification unit is configured to generate the target signal φ_{tgt}. The specification unit is also configured to output information about the target signal φ_{tgt} to the modulator. In particular, the specification unit 13, 14 has a ramp generator 13 which serves to generate a ramp signal. Via an integrator, the target signal φ_{tgt} is produced. The ramp signal is in particular also output to the modulator.

According to the present disclosure, the phase ascertaining unit preferably has a digital-to-time converter and a phase measurement unit connected in series. The phase measurement unit is, for example, a time-to-digital converter. The digital-to-time converter is, in particular, installed upstream of the phase measurement unit. A reference signal can be supplied to the digital-to-time converter, and an output of the digital-to-time converter can be supplied to the phase measurement unit. In particular, the output of the digital-to-time converter can be supplied to the phase measurement unit as a clock pulse signal. The digital-to-time converter is used in particular to apply a dither to the reference signal due to the relatively coarse quantization steps of the phase measurement unit, in particular the time-to-digital converter. The feedback signal can also be supplied to the phase measurement unit. In this way, the measurement signal φₘₑₐₛ can be obtained simply and reliably.

### BRIEF DESCRIPTION OF THE DRAWINGS

In the following, exemplary embodiments of the present disclosure are described in detail with reference to the figures.

FIG. 1 is a schematic representation of a phase-locked loop according to an exemplary embodiment of the present disclosure,

FIG. 2 is a schematic representation of a first variant of a combination including a divider unit, counter unit and sampler unit of the phase-locked loop according to the exemplary embodiment of the present disclosure for division ratios as a power of two.

FIG. 3 is a schematic representation of a second variant of a combination including a divider unit, counter unit, and sampler unit of the phase-locked loop according to the exemplary embodiment of the present disclosure for other division ratios.

FIG. 4 is a schematic representation of a third variant of a separate divider unit with a sampler unit and counter unit of the phase-locked loop according to the exemplary embodiment of the present disclosure.

### DETAILED DESCRIPTION OF EXAMPLE EMBODIMENTS

Preferably, identical components, elements, and/or units are provided with identical reference signs in all figures.

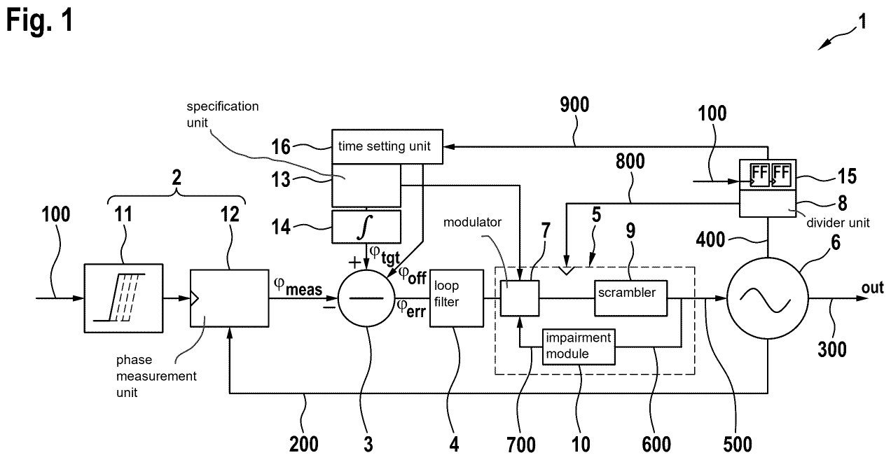

FIG. 1 schematically shows a phase-locked loop 1 (PLL). In particular, the phase-locked loop 1 is a digital phase-locked loop (DPLL) or an all-digital phase-locked loop (ADPLL).

The phase-locked loop 1 is used to track a phase of an oscillator 6 according to the phase of a reference signal 100. In the exemplary embodiment shown, a digitally controlled oscillator 6 (DCO) is provided. The phase-locked loop 1 has a phase ascertaining unit 2, which is configured to detect a phase difference between a reference signal 100 and a feedback signal 200 and to output a measurement signal φₘₑₐₛ representing the phase difference.

The phase ascertaining unit 2 has a digital-to-time converter 11 and a phase measurement unit 12 connected in series. The phase measurement unit 12 is, for example, a time-to-digital converter. The digital-to-time converter 11 is installed upstream of the phase measurement unit 12 and is used to apply a dither to the reference signal 100, which can be supplied to the digital-to-time converter 11. The phase measurement unit 12 can be supplied with an output of the digital-to-time converter 11, wherein the applied dithering is advantageous for taking into account the relatively coarse quantization steps of the time-to-digital converter as the phase measurement unit 12. The feedback signal 200 can also be supplied to the phase measurement unit 12.

The phase-locked loop 1 also has a modulator unit 5, wherein the modulation in the illustrated exemplary embodiment is applied as a two-point modulation. For this purpose, a specification unit 13, 14 is provided, which is configured to generate a target signal φ_{tgt}. In the illustrated exemplary embodiment, the specification unit 13, 14 has a ramp generator 13 which is used to generate a ramp signal. Via an integrator 14, this becomes the target signal φ_{tgt}. The ramp signal is in particular also output to the modulator unit 5.

A phase deviation ascertaining unit 3 is configured to generate an error signal φₑᵣᵣ from the measurement signal φₘₑₐₛ and the target signal φ_{tgt}. Due to the target signal φ_{tgt} being taken into account, modulation takes place at a first point in order to achieve the aforementioned two-point modulation.

The phase-locked loop 1 has a loop filter 4 for filtering the error signal φₑᵣᵣ, wherein the output of the loop filter 4 can be supplied to the modulator unit 5. The loop filter 4 is, for example, a digital loop filter (DLF).

The modulator unit 5 is configured to modulate the filtered error signal and to generate a tune signal 500. The oscillator 6 can be controlled by the tune signal 500, wherein the oscillator 6 is configured to generate an output signal 300 from the tune signal 500. The feedback signal 200 supplied to the phase ascertaining unit 2 is derived from the output signal 300 of the phase-locked loop 1.

The modulator unit 5 represents a second point of the two-point modulation. The modulator unit 5 has a modulator 7 and a scrambler 9 installed downstream of the modulator 7. The modulator 7, for example, is a delta-sigma modulator. The scrambler 9 is used primarily for mismatch shaping and/or transition control. The scrambler 9 is trained to provide metadata 600 that describe basic properties of the selection of active elements of the oscillator 6.

The modulator unit 5 has an impairment module 10. The impairment module 10 is used to ascertain signal impairment from the metadata 600 of the scrambler 9 and from predefined calibration data 400. The signal impairments 700 are fed back to the modulator 7.

The phase-locked loop 1 also has a divider unit 8 and a sampler unit 15. The modulation by the modulator unit 5 is controlled by a modulator clock pulse signal 800, wherein the modulator clock pulse signal 800 is created from an oscillator clock pulse signal 400 of the oscillator 6 by means of the divider unit 8. The divider unit 8 is therefore configured to create the modulator clock pulse signal 800 and supply it to a clock pulse input of the modulator unit 5. In this way, a relationship exists between the oscillator clock pulse signal 400 and the modulator clock pulse signal 800 created by division, but the relationship between the reference signal 100 and the modulator clock pulse signal 800 is unknown. This information is, however, relevant if the modulation is to be precisely aligned with the reference signal 100. Therefore, the sampler unit 15 is provided. The sampler unit 15 is configured to detect a mismatch 900 between the reference signal 100 and the modulator clock pulse signal 800. This allows the mismatch 900 to be used when ascertaining the error signal φₑᵣᵣ.

In particular, a time setting unit 16 is provided in the illustrated exemplary embodiment which is configured to ascertain an offset φ_{off} from the mismatch 900. The offset φ_{off} ascertained in this way is supplied to the phase deviation ascertaining unit 3. In order to generate the fault signal φₑᵣᵣ, the phase ascertaining unit therefore uses the measurement signal φₘₑₐₛ, the offset φ_{off} and the target signal φ_{tgt}. This ensures that the mismatch 900 is taken into account during modulation, so that the modulation is correctly aligned with the reference signal 100.

In principle, it is provided that the sampler unit 15 is configured to sample a state of flip-flops of the divider unit 8. This allows the state of the divider unit 8 to be identified. Each sampling step can be performed according to the clock pulse of the reference signal 100. This allows the mismatch 900 to be reliably determined. The exact determination of the mismatch 900 is dependent on the specific design of the divider unit 8. In the following, the different variations will be explained.

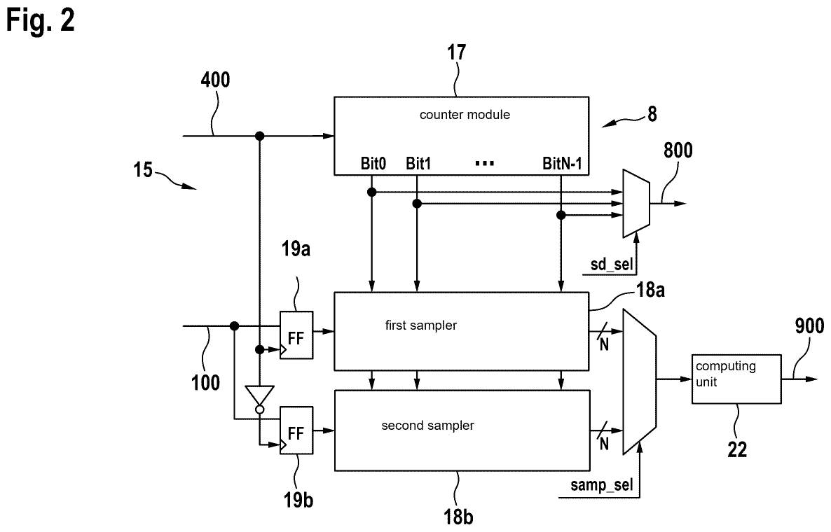

FIG. 2 schematically shows a first variant in which the division ratio of the divider unit 8 is a power of 2. In this case, the divider unit 8 has an N-bit counter module 17, wherein N is a natural number, for detecting the clock pulses of the oscillator clock pulse signal 400, wherein the counter module 17 directly has the necessary states to detect the mismatch 900. In this case, the division is very simple, in that one of the N-bits is used as the modulator clock pulse signal 800. In FIG. 2, this is represented by a plurality multiplexer that outputs one of the N-bits as a modulator clock pulse signal 400. By choosing the appropriate bit k, the corresponding division ratio 2″ can be set.

The sampler unit 15 has at least a first sampler 18a and a second sampler 18b for sampling the N-bits of the counter module 17. The first sampler 18a can be controlled by a data output of a first control flip-flop 19a and the second sampler 18b by a second control flip-flop 19b. The first sampler 18a is provided for rising edges, the second sampler 18b for falling edges. Accordingly, the oscillator clock pulse signal 400 can be considered both positively and negatively. This enables reliable detection of the oscillator clock pulse signal 400. A relevant data input of the control flip-flops 19a, 19b is the reference signal 100. A clock pulse input of the first control flip-flop 19a is the oscillator clock pulse signal 400. The second control flip-flop 19b uses the oscillator clock pulse signal 400 inverted as its clock pulse input in order to thereby react to falling edges. The first sampler 18a and the second sampler 18b are connected via a multiplexer which selects the output result of the two samplers 18a, 18b.

The sampler unit 15 has a computing unit 22 which is installed downstream from said multiplexer and accordingly optionally receives the output of the first sampler 18a or the output of the second sampler 18b. The computing unit 22 is configured to ascertain the mismatch 900 on the basis of the division ratio of the divider unit 8 and the output of the first sampler 18a or second sampler 18b. Since the division ratio is a power of 2, this can be done very easily. In particular, the current duration t_{lag} until the next rising edge of the modulator clock pulse signal 800 can be easily ascertained from the following formula:

$${t}_{lag} = {T}_{OSC} \times ( \frac{DIV}{2} - cnt\_samp )$$

In this case, T_{OSC} is the period of the oscillator, DIV the division ratio, and cnt_samp the output selected by the multiplexer from the two samplers 18a, 18b.

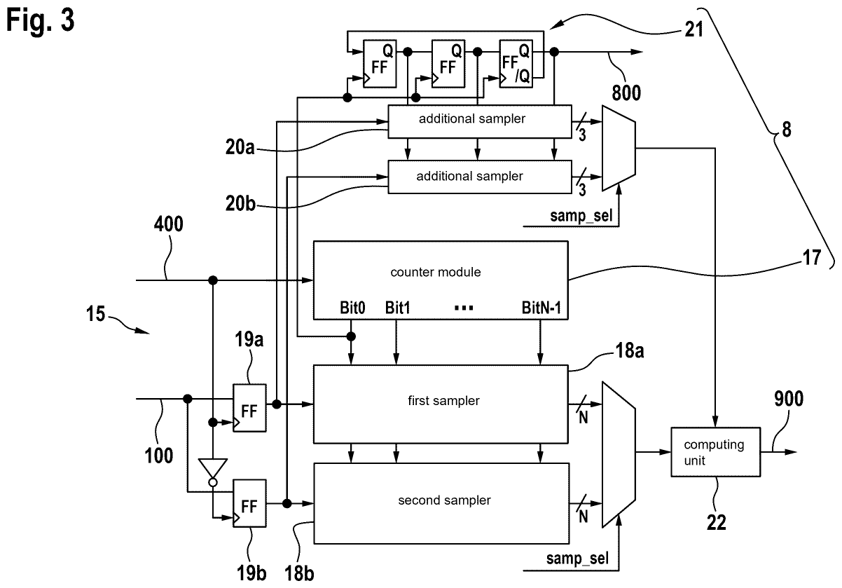

A second variant is shown in FIG. 3. This allows for other division ratios than powers of 2. In this regard, divider unit 8 has at least one additional shift register 21. The additional shift register 21, for example, is formed by interconnected flip-flops. Furthermore, it is provided that the additional shift register is clocked by one of the N-bits of the counter module 17. Accordingly, a further division is possible, wherein the size of the additional shift register 21 determines the division ratio.

Instead of the bit of the counter module 17 that clocks the additional shift register 21, a bit of the additional shift register 21 is output as a modulator clock pulse signal 800. In the variant shown in FIG. 3, the additional shift register 21 is a 3-bit shift register. This allows a division ratio of 12.

In order to also be able to sample the state of the additional shift register 21, the sampler unit 15 has at least one additional sampler 20a, 20b, controllable by the control flip-flop 19a, 19b, for sampling the additional shift register 21. Again, a first additional sampler 20a is provided for rising edges, the second additional sampler 20b for falling edges.

Again, a computing unit 22 is provided. The computing unit 22 is configured to ascertain the deviation 900 on the basis of the division ratio of the divider unit 8 and the output of the first sampler 18a or second sampler 18b, as well as of the first additional sampler 20a or second additional sampler 20b, wherein the respective multiplexers select between the outputs of samplers 18a, 18b and additional samplers 20a, 20b. In particular, the current duration t_{tag} until the next rising edge of the modulator clock pulse signal 800 can be easily ascertained from the following formula:

$${t}_{l a g} = {T}_{O S C} \times ( \frac{DIV}{2} - 2 k \times t h e r m 2 b i n ( d i {v}_{s a m p} ) - cnt\_samp [ k - 1 ] )$$

In this case, T_{OSC} is the period of the oscillator, DIV is the divider ratio, div_samp is the output of the additional sampler, and cnt_samp[k−1] is the output of the sampler concerning the bits clocking the additional sampler k. The function therm2bin(x) is a classic thermometer code for binary code conversion, i.e. for example 000->0, 001->1, 111->3, 100->5.

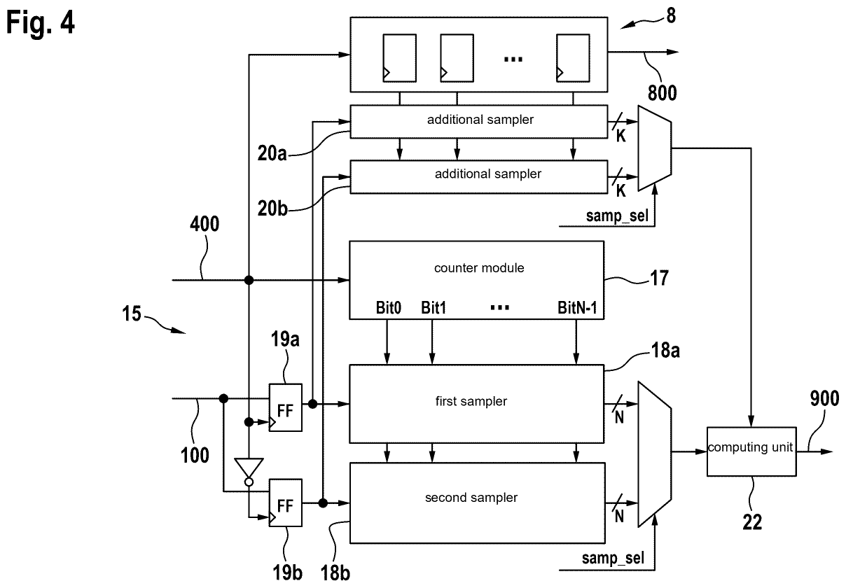

A third variant is shown in FIG. 4. In this case, any divider unit 8 is used, wherein the principles explained above are still applicable.

In the third variant, the sampler unit 15 has an N-bit counter module 17 for detecting the clock pulses of the oscillator clock pulse signal 400, wherein N is a natural number. In contrast to the variants described above, this counter module 17 is not used for actual division. Rather, the divider unit 8 is configured separately therefor for outputting the modulator clock pulse signal 800.

The sampler unit 15 in turn has a first sampler 18a and a second sampler 18b which are configured analogously to the first or second variant and are provided for sampling the N-bits of the counter module 17. The first sampler 18a and the second sampler 18b are controlled by a relevant data output of a first control flip-flop 19a and a second control flip-flop 19b, which data outputs are configured and arranged analogously to the first or second variant.

For sampling the divider unit 8, the sampler unit 15 has a first additional sampler 20a and a second additional sampler 20b analogous to the second variant. The additional samplers 20a, 20b can be controlled by the corresponding control flip-flops 19a, 19b.

The sampler unit 15 also has a computing unit 22 analogous to the first or second variant. The computing unit is therefore configured to ascertain the mismatch 900 on the basis of the division ratio of the divider unit 8 and the output of the first sampler 18a or second sampler 18b as well as of the first additional sampler 20a or second additional sampler 20b. The formula to be used for this purpose is specific to the exact embodiment of the divider unit, in particular specific to the concrete implementation of the divider unit by an electrical circuit.

1-10. (canceled)

11. A phase-locked loop, comprising:
a phase ascertaining unit configured to detect a phase of a reference signal and to output a measurement signal;
a phase deviation ascertaining unit configured to generate an error signal from the measurement signal and from a target signal;
a loop filter configured to filter the error signal;
a modulator unit configured to modulate the filtered error signal and to generate a tune signal; and
an oscillator configured to generate an output signal from the tune signal;
wherein a feedback signal derived from an output signal of the phase-locked loop is supplied to the phase ascertaining unit; and
wherein the phase-locked loop further comprises:
a divider unit configured to create a modulator clock pulse signal from an oscillator clock pulse signal of the oscillator and to supply the modulator clock pulse signal to the modulator unit, and
a sampler unit configured to detect a mismatch between the reference signal and the modulator clock pulse signal, in order to take into account the mismatch when ascertaining the error signal.

12. The phase-locked loop according to claim 11, wherein the sampler unit is configured to sample a state of flip-flops of the divider unit, wherein each sampling step can be performed according to a clock pulse of the reference signal.

13. The phase-locked loop according to claim 11, wherein:
the divider unit has an N-bit counter module configured to detect clock pulses of the oscillator clock pulse signal,
N is a natural number,
one of the N-bits can be output as the modulator clock pulse signal,
the sampler unit has at least one sampler configured to sample the N-bits of the counter module, the at least one sampler being controllable by a data output of a control flip-flop,
a data input of the control flip-flop is the reference signal and a clock pulse input of the control flip-flop is the oscillator clock pulse signal, and
the sampler unit includes a computing unit configured to ascertain the mismatch based on a division ratio of the divider unit and an output of the at least one sampler.

14. The phase-locked loop according to claim 13, wherein:
the divider unit includes at least one additional shift register formed by interconnected flip-flops, which is clocked by one bit of the N-bits of the counter module,
a bit of the at least one additional shift register can be output as the modulator clock pulse signal instead of the bit of the counter module clocking the additional shift register,
the sampler unit has at least one additional sampler, controllable by the control flip-flop, for sampling the additional shift register, and
the computing unit is configured to ascertain the mismatch based on the division ratio of the divider unit and the output of the sampler and an output of the additional sampler.

15. The phase-locked loop according to claim 11, wherein:
the sampler unit includes an N-bit counter module configured to detect clock pulses of the oscillator clock pulse signal,
N is a natural number,
the divider unit is configured to output the modulator clock pulse signal,
the sampler unit includes at least one sampler configured to sample N-bits of the counter module, the at least one sampler being controllable by a data output of a control flip-flop,
wherein a data input of the control flip-flop is the reference signal and a clock pulse input of the control flip-flop is the oscillator clock pulse signal,
the sampler unit includes at least one additional sampler, controllable by the control flip-flop, for sampling the divider unit, and
the sampler unit includes a computing unit configured to ascertain the mismatch based on a division ratio of the divider unit and the output of the sampler and an output of the at least one additional sampler.

16. The phase-locked loop according to claim 11, further comprising:
a time setting unit configured to ascertain an offset from the mismatch, wherein the offset can be supplied to the phase deviation ascertaining unit for generating the error from the measurement signal, the offset, and the target signal

17. The phase-locked loop according to claim 11, wherein:
the modulator unit includes a modulator and a scrambler installed downstream from the modulator, and
the modulator unit includes an impairment module configured to ascertain signal impairment from metadata of the scrambler and from predefined calibration data and which is configured to feed signal impairments back to the modulator.

18. The phase-locked loop according to claim 11, wherein the modulator is a delta-sigma modulator.

19. The phase-locked loop according to claim 11, further comprising:
a specification unit configured to generate the target signal, wherein the specification unit is also configured to output information about the target signal to the modulator.

20. The phase-locked loop according to claim 11, wherein the phase ascertaining unit includes a digital-to-time converter and a phase measurement unit connected in series, wherein a reference signal can be supplied to the digital-to-time converter, and wherein an output of the digital-to-time converter and the feedback signal can be supplied to the phase ascertaining unit.
